(19) United States
(12) Patent Application Publication
(10) Pub. No.: US 2023/0119285 A1
(43) Pub. Date: Apr. 20, 2023

(54) CRYSTALLIZATION METHOD OF AMORPHOUS SILICON

(71) Applicant: Samsung Display Co., LTD., Yongin-si (KR)

(72) Inventors: Ji-Hwan KIM, Hwaseong-si (KR); Hiroshi OKUMURA, Hwaseong-si (KR)

(73) Assignee: Samsung Display Co., LTD., Yongin-si (KR)

(21) Appl. No.: 17/892,342

(22) Filed: Aug. 22, 2022

(30) Foreign Application Priority Data
Oct. 19, 2021 (KR) 10-2021-0139370

(51) Int. Cl. H01L 21/02

(52) U.S. Cl. CPC H01L 21/02675; H01L 21/02592; H01L 21/02532; H01L 2021/775

(57) ABSTRACT

A crystallization method of amorphous silicon includes forming amorphous silicon on a substrate; first-irradiating a laser beam on the amorphous silicon while moving the substrate in a first direction; moving a position of the substrate in a second direction perpendicular to the first direction, and second-irradiating a laser beam on the amorphous silicon while moving the substrate in an opposite direction to the first direction.

### CROSS-REFERENCE TO RELATED APPLICATION(S)

This application claims priority to and benefits of Korean Patent Application No. 10-2021-0139370 under 35 U.S.C. § 119, filed in the Korean Intellectual Property Office (KIPO) on Oct. 19, 2021, the entire contents of which are incorporated herein by reference.

### BACKGROUND

### 1. Technical Field

The disclosure relates to a crystallization method of amorphous silicon.

### 2. Description of the Related Art

Generally, a display device such as a liquid crystal display device or an organic light emitting display device uses a thin film transistor to control light emission of each pixel. Since such a thin film transistor includes polysilicon, a step of forming a polysilicon layer on a substrate is performed in a process of manufacturing a display device. An amorphous silicon layer is formed on a substrate, and the amorphous silicon layer is crystallized to form the polysilicon layer. The crystallizing of the amorphous silicon layer may be performed by irradiating a laser beam on the amorphous silicon layer.

The above information disclosed in this Background section is only for enhancement of understanding of the background of the invention, and therefore it may contain information that does not form the prior art that is already known in this country to a person of ordinary skill in the art.

### SUMMARY

Embodiments are to provide a crystallization method of amorphous silicon that may reduce visibility of a stain by adjusting a position of a substrate for each irradiation step of the laser beam.

However, embodiments of the disclosure are not limited to those set forth herein. The above and other embodiments will become more apparent to one of ordinary skill in the art to which the disclosure pertains by referencing the detailed description of the disclosure given below.

An embodiment provides a crystallization method of amorphous silicon, including forming amorphous silicon on a substrate; first-irradiating a laser beam on the amorphous silicon while moving the substrate in a first direction; moving a position of the substrate in a second direction perpendicular to the first direction, second-irradiating a laser beam on the amorphous silicon while moving the substrate in an opposite direction to the first direction.

The laser beam may be emitted from a laser beam source. The laser beam emitted from the laser beam source may be reflected by a polygonal mirror that rotates around a rotation axis, and then may be irradiated onto the substrate.

The polygonal mirror may include a first reflective surface and a second reflective surface, and a moving distance of a laser beam reflected by the first reflective surface on the substrate and a moving distance of a laser beam reflected by the second reflective surface on the substrate may be equal to each other.

The laser beam reflected by the polygonal mirror may be sequentially reflected by a first mirror and a second mirror and then may be irradiated onto the substrate.

The first mirror may have a convex reflective surface, and the second mirror may have a concave reflective surface.

A moving distance of the substrate in the first direction in the first-irradiating of the laser beam and a moving distance of the substrate in the opposite direction to the first direction in the second-irradiating of the laser beam may be equal to each other.

The crystallization method of amorphous silicon may further include, moving the position of the substrate in an opposite direction to the second direction; and third-irradiating a laser beam on the amorphous silicon while moving the substrate in the first direction.

A moving distance in the first direction in the third-irradiating of the laser beam and a moving distance in the first direction in the first-irradiating of the laser beam may be equal to each other.

The crystallization method of amorphous silicon may further include, moving the position of the substrate in the second direction; fourth-irradiating a laser beam on the amorphous silicon while moving the substrate in the opposite direction to the first direction.

A moving distance in the opposite direction to the first direction in the fourth-irradiating of the laser beam and a moving distance in the first direction in the third-irradiating of the laser beam may be equal to each other.

In the second-irradiating of the laser beam, a moving distance of the substrate in the second direction may be in a range of about 1 cm to about 10 cm.

Another embodiment provides a crystallization method of amorphous silicon, including forming amorphous silicon on a substrate; vibrating, while moving the substrate in a first direction, vibrating the substrate in a second direction perpendicular to the first direction, and first-irradiating a laser beam on the amorphous silicon during the moving; moving a position of the substrate in the second direction; and vibrating the substrate in the second direction while moving the substrate in an opposite direction to the first direction, and second-irradiating a laser beam on the amorphous silicon during the moving.

A width of vibration in the second direction in the first-irradiating of the laser beam and a width of vibration in the second direction in the second-irradiating of the laser beam may be different from each other.

A moving distance of the substrate in the first direction in the first-irradiating of the laser beam and a moving distance of the substrate in the opposite direction to the first direction in the second-irradiating of the laser beam may be equal to each other.

The crystallization method of amorphous silicon may further include moving the position of the substrate in an opposite direction to the second direction; and vibrating the substrate in the second direction while moving the substrate in the first direction, and third-irradiating a laser beam on the amorphous silicon during the moving.

The crystallization method of amorphous silicon may further include moving the position of the substrate in the second direction; and vibrating the substrate in the second direction while moving the substrate in the opposite direction to the first direction, and fourth-irradiating a laser beam on the amorphous silicon during the moving.

A width of vibration in the second direction in the third-irradiating and a width of vibration in the second direction in the fourth-irradiating may be different from each other.

In the second-irradiating of the laser beam, a moving distance of the substrate in the second direction may be in a range of about 1 cm to about 10 cm.

The laser beam may be emitted from a laser beam source. The laser beam emitted from the laser beam source may be reflected by a polygonal mirror that rotates around a rotation axis, and then may be irradiated onto the substrate.

The laser beam reflected by the polygonal mirror may be sequentially reflected by a first mirror and a second mirror and then may be irradiated onto the substrate.

According to the embodiments, it is possible to provide a crystallization method of amorphous silicon that may reduce visibility of a stain by adjusting a position of a substrate for each irradiation step of the laser beam.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 schematically illustrates a laser crystallization apparatus according to an embodiment of the disclosure;

FIG. 2 schematically illustrates a crystallization silicon layer crystallized in case that a defect is formed in a first mirror;

FIG. 3 schematically illustrates a crystallization silicon layer stained by a defect in a first mirror;

FIG. 4 schematically illustrates an image of a line stain occurring in actual crystallized silicon;

FIGS. 5 to 7 schematically illustrate a crystallization process according to an embodiment step by step;

FIG. 8 schematically illustrates a crystallization silicon layer crystallized through laser beam irradiation of FIGS. 5 to 7;

FIGS. 9 to 11 schematically illustrate a crystallization process according to another embodiment;

FIG. 12 schematically illustrates a crystallization silicon layer crystallized through laser beam irradiation of FIGS. 9 to 11;

FIGS. 13 to 16 schematically illustrate a process of crystallizing an amorphous silicon layer by repeatedly irradiating a substrate 4 times;

FIG. 17 schematically illustrates a crystallization silicon layer crystallized through laser beam irradiation of FIGS. 13 to 16;

FIGS. 18 and 19 schematically illustrate a process of crystallizing an amorphous silicon layer by repeatedly irradiating a laser beam on a substrate 2 times; and

FIG. 20 schematically illustrates a crystallization silicon layer crystallized through the laser beam irradiation of FIGS. 18 and 19.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices of methods disclosed herein. It is apparent, however, that various embodiments may be practiced without these specific details of with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing exemplary features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concept.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Also, like reference numerals denote like elements.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context explicitly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Further, in the specification, the phrase “in a plan view” or “on a plane” means when an object portion is viewed from above, and the phrase “in a cross-sectional view” or “on a cross-section” means when a cross-section taken by vertically cutting an object portion is viewed from the side.

Hereinafter, a laser crystallization apparatus and a laser crystallization method according to an embodiment is described in detail with reference to the accompanying drawings below.

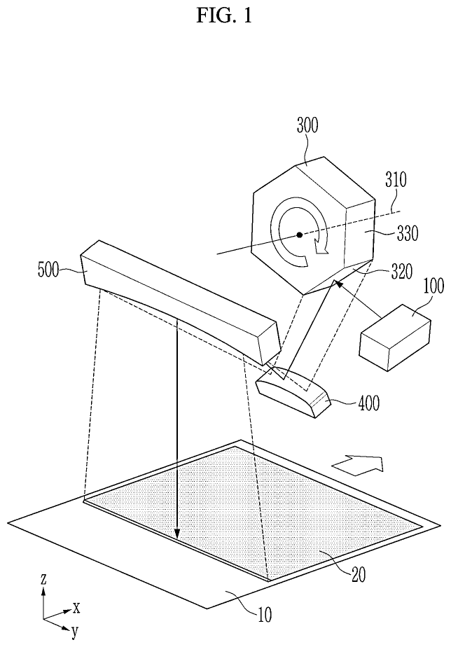

FIG. 1 schematically illustrates a laser crystallization apparatus according to an embodiment of the disclosure. As shown in FIG. 1, the laser crystallization apparatus according to the embodiment may include a laser beam source 100, a polygonal mirror 300, a first mirror 400, and a second mirror 500.

The laser beam source 100 may emit a linearly polarized laser beam. The laser beam source 100 may include a laser beam source and a linear polarizer. For example, the laser beam source 100 may use a fiber laser. The fiber laser may be advantageous in controlling output in a wide range, maintaining at a low maintenance cost, and operating at high efficiency.

The polygonal mirror 300 may reflect an incident laser beam from the laser beam source 100. The polygonal mirror 300 may rotate around a rotation axis 310. The laser beam emitted from the laser beam source 100 may be reflected by the polygonal mirror 300 and reach an amorphous silicon layer 20 on a substrate 10. Accordingly, the amorphous silicon layer 20 may be crystallized to become a crystallization silicon layer.

In case that the polygonal mirror 300 rotates, the laser beam may be irradiated to all or most of an area of the amorphous silicon layer 20. The laser beam reflected from the polygonal mirror 300 may be irradiated to the amorphous silicon layer 20, and as the polygonal mirror 300 rotates, a point on the amorphous silicon layer 20 to which the laser beam reaches is changed (e.g., changed to be crystalized). As shown in FIG. 1, in case that the laser beam emitted from the laser beam source 100 arrives on a first reflective surface 320 of the polygonal mirror 300 and in case that the polygonal mirror 300 rotates in a direction indicated by an arrow around the rotation axis 310, the point on the amorphous silicon layer 20 where the laser beam reaches is moved in a +y direction. In the specification, the +y direction means a direction indicated by a y arrow on the illustrated direction axis, and a −y direction means an opposite direction to the y arrow.

For example, the laser beam emitted from the laser beam source 100 may move on the first reflective surface 320 of the polygonal mirror 300, and the point on the amorphous silicon layer 20 to which the laser beam reaches may move in the +y direction. For example, the point on the amorphous silicon layer 20 may move in the +y direction during the moving of the laser beam on the first reflective surface 320.

In case that the polygonal mirror 300 is further rotated and the laser beam emitted from the laser beam source 100 arrives on a second reflective surface 330 of the polygonal mirror 300, the laser beam moves again in the +y direction on the amorphous silicon layer 20. A moving length of the laser beam reflected by the second reflective surface 330 may be the same as a moving length of the laser beam reflected by the first reflective surface 320.

For example, the amorphous silicon layer 20 is irradiated once in the y-direction for each reflective surface of the polygonal mirror 300, and in case that the substrate 10 is moved in an x direction by using a stage while rotating the polygonal mirror 300, all or most of the area of the amorphous silicon layer 20 may be irradiated with a laser beam. The x direction may intersect the y direction. For example, the x direction may be perpendicular to the y direction.

In other embodiments, the laser beam reflected from the polygonal mirror 300 may immediately reach the amorphous silicon layer 20. However, in the embodiment, a path of the laser beam reflected from the polygonal mirror 300 may be adjusted by using the first mirror 400 and the second mirror 500 as shown in FIG. 1, and then, it may allow the laser beam to reach the amorphous silicon layer 20.

As shown in FIG. 1, the first mirror 400 may have a convex reflective surface, and the second mirror 500 may have a concave reflective surface. Referring to FIG. 1, in case that the laser beam is reflected from a point far from the second reflective surface 330 among points in the first reflective surface 320 of the polygonal mirror 300, the laser beam may be irradiated to an edge of the amorphous silicon layer 20 in the −y direction. In case that the laser beam is reflected from a point adjacent to the second reflective surface 330 among the points in the first reflective surface 320 of the polygonal mirror 300, the laser beam may be irradiated near the edge of the amorphous silicon layer 20 in the +y direction.

Accordingly, in case that the laser beam is reflected by the first reflective surface 320 and the polygonal mirror 300 rotates, a length of the laser beam irradiated area of the amorphous silicon layer 20 may correspond to a width of the amorphous silicon layer 20 in the y direction.

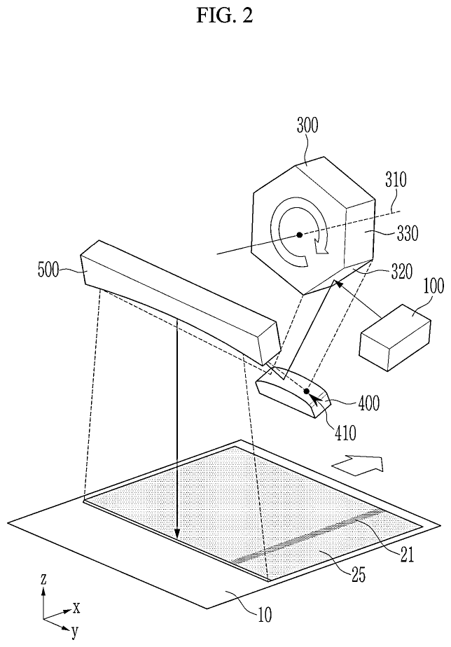

In case that the laser beam is irradiated in this way, the entire area of the amorphous silicon layer 20 may be uniformly crystallized, but in case that there is a defect 410 (e.g., refer to FIG. 2) in the first mirror 400, a line stain may occur in a scan direction due to overlap of a shadow caused by the defect 410. Thus, the defect 410 may be (or may include) contamination or damage to the first mirror 400. FIG. 2 schematically illustrates a crystallization silicon layer crystallized in case that there is the defect 410 in the first mirror 400. As shown in FIG. 2, the shadow overlaps due to the defect 410 of the first mirror 400, and a stain 21 occurs due to a difference in crystallization characteristics in the shadow part.

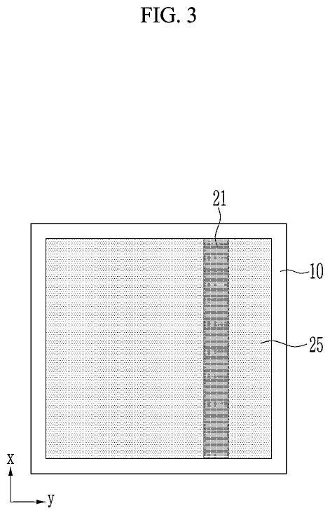

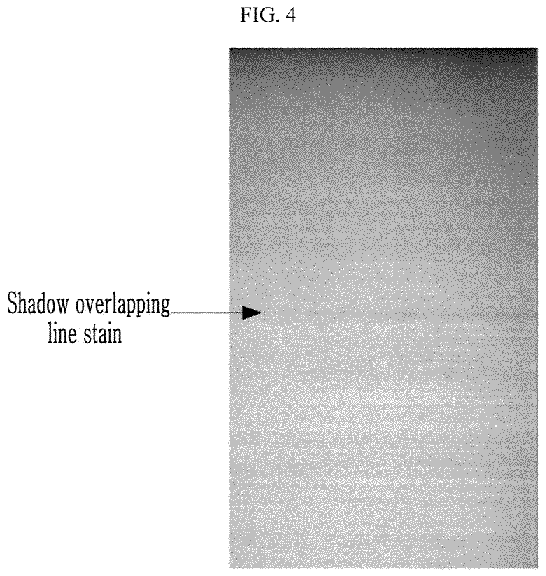

FIG. 3 schematically illustrates the case in which the stain 21 occurs on the crystallization silicon layer 25 due to the defect 410 of the first mirror 400. In FIG. 3, the substrate 10 may move in the x direction, and the laser beam may be scanned in they direction. As shown in FIG. 3, a degree of crystallization is changed in some areas due to the overlap of the shadow caused by the defect 410 of the first mirror 400, which is viewed as the stain 21 as shown in FIG. 3. FIG. 4 schematically illustrates an image of a line stain occurring in actual crystallized silicon.

As described above, since the laser beam moves the same distance every time the amorphous silicon layer 20 is scanned in the y-direction once, the stain 21 may be formed at the same position for each scan, and thus as shown in FIGS. 3 and 4, the stain 21 may be viewed as a continuous line.

Accordingly, the crystallization method of amorphous silicon according to the embodiment may control the position and movement speed of the substrate during crystallization, so that the stains 21 may not overlap each other for each scan. Thus, the stains 21 may not be readily viewed. Description of removing the stains 21 is provided below.

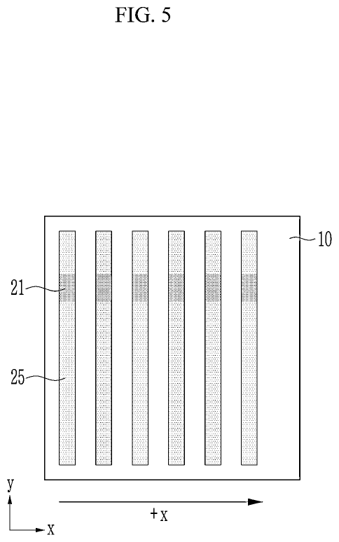

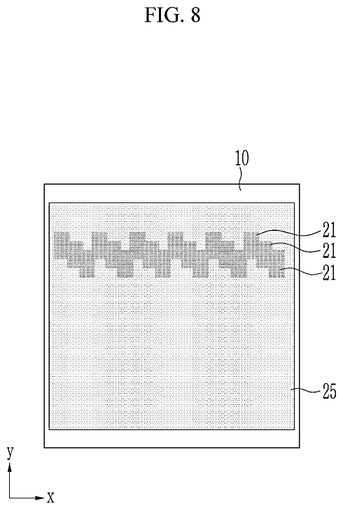

FIGS. 5 to 7 schematically illustrate a crystallization process according to an embodiment step by step. FIG. 8 illustrates the crystallization silicon layer 25 crystallized through the crystallization of FIGS. 5 to 7.

Referring to FIG. 5, the amorphous silicon layer is first crystallized while moving the substrate 10 in a +x direction. In the specification, the +x direction means a direction indicated by the x arrow on the directional axis shown in each drawing, and the −x direction means an opposite direction of the x arrow. Similarly, the +y direction means a direction indicated by the y arrow on the directional axis shown in each drawing, and the −y direction means an opposite direction of the y arrow.

FIG. 5 illustrates the crystallization silicon layer 25 crystallized by laser beam irradiation among the amorphous silicon. A movement speed in the x direction of the substrate 10 may be faster than a crystallization speed of the entire amorphous silicon layer by the movement of the substrate 10. The crystallization speed of the entire amorphous silicon layer by the movement of the substrate 10 is referred to as a reference speed, and the movement speed of the substrate 10 may be three times the reference speed. Since the substrate 10 moves at the movement speed faster than the reference speed by three times, a degree of crystallization of the amorphous silicon layer after the movement of the substrate 10 may be the same as that shown in FIG. 5. For example, since the substrate 10 rapidly moves, the crystallization may not be performed as a whole, but the crystallization may occur only in some areas of the crystallization silicon layer 25. FIG. 5 illustrates the crystallization silicon layer 25 partially crystallized by irradiating the laser beam.

For better comprehension and ease of description, FIG. 5 illustrates the crystallization silicon layer 25 crystallized by irradiating the laser beam as a straight line, but the crystallization silicon layer 25 may be crystallized by irradiating the laser beam in a diagonal direction. FIG. 5 illustrates the stain 21 formed by the defect 410 of the first mirror 400 having different crystallinity from that of other areas. Comparing with the embodiment of FIG. 3, in the embodiment of FIG. 5, since the substrate 10 is quickly moved and the laser beam is irradiated, the stains 21 may not be continuous but are formed to be spaced apart from each other.

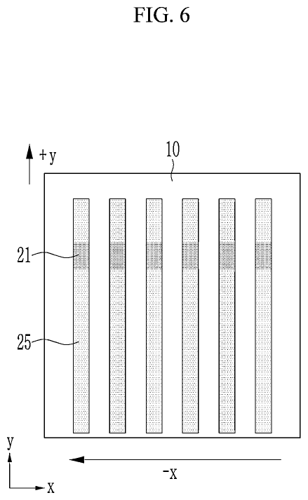

Referring to FIG. 6, in case that the substrate 10 is moved again in the −x direction, the amorphous silicon layer may be crystallized by irradiating the laser beam thereon. FIG. 6 illustrates the crystallization silicon layer 25 crystallized by the irradiation with the laser beam and the stain 21 that is not sufficiently crystallized. In the step of FIG. 6, the substrate 10 may move in the −x direction in a state in which it further moves in the +y direction than a position (hereinafter, a reference position) of the substrate 10 in FIG. 5. Accordingly, as shown in FIG. 6, the formation position of the stain 21 may be lower in the y direction than the position of the stain 21 shown in FIG. 5. For example, the position of the stain 21 formed in the step of FIG. 6 may be shifted in the y direction (e.g., −y direction) from the position of the stain 21 formed in the step of FIG. 5. Since the substrate 10 moves in the +y direction from the reference position and the laser beam is irradiated, the position of the stain 21 formed in the step of FIG. 6 may be lower than the position of the stain 21 formed in the step of FIG. 5. The moving distance (or shifted distance) of the stain 21 in they direction may be in a range of about 1 cm to about 10 cm. However, this is only an example, and the moving distance in the y direction may vary according to embodiments.

The distance (e.g., moving distance of substrate 10) moved in the +x direction in FIG. 5 and the distance (e.g., moving distance of substrate 10) moved in the −x direction in FIG. 6 may be the same. In the specification, the same distance means that the difference therebetween is less than 10%.

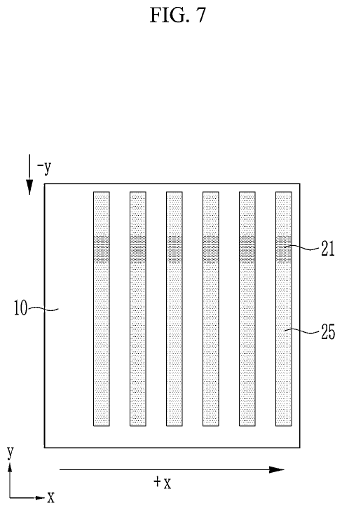

Referring to FIG. 7, in case that the substrate 10 is moved again in the +x direction, the amorphous silicon layer may be crystallized by irradiating the laser beam thereon. FIG. 7 illustrates the crystallization silicon layer 25 crystallized by the irradiation with the laser beam and the stain 21 that is not sufficiently crystallized. The substrate 10 may move in the +x direction in a state in which it further moves in the −y direction than a position (hereinafter, a reference position) of the substrate 10 in FIG. 5. Accordingly, as shown in FIG. 7, the formation position of the stain 21 may be higher in the y direction than the position of the stain 21 shown in FIG. 5. This is because the laser beam is irradiated in the state in which the substrate 10 moves in the −y direction. The moving distance (or shifted distance) of the stain 21 in they direction based on the reference position of the substrate may be in a range of about 1 cm to about 10 cm. However, this is only an example, and the moving distance in the y direction may vary according to embodiments. The moving distance of the substrate 10 in the +x direction in FIG. 7 may be the same as the moving distance of the substrate 10 in the +x direction in FIG. 5.

FIG. 8 schematically illustrates the crystallization silicon layer 25 crystallized by irradiating the laser beam through the processes of FIGS. 5 to 7 as described above. Referring to FIG. 8, the stains 21 may be dispersed and positioned at various positions in the crystallization silicon layer 25 without being displayed as a line (or single line). In case that the laser beam is irradiated as shown in FIGS. 5 to 7, the laser beam may be irradiated on different positions of the substrate 10 in the y direction for each irradiation process. Since the position of the substrate 10 varies for each irradiation, the position of the stains 21 also varies for each irradiation. Accordingly, the stains 21 formed during each irradiation do not overlap as one, but are dispersed from each other, so that visibility of the stains 21 may be lowered. For example, comparing the embodiments of FIGS. 3 and 8, in the embodiment of FIG. 3 in which the entire amorphous silicon layer 20 is continuously crystallized at once, the stains 21 may overlap and be viewed as a single line. However, in the embodiment of FIG. 8, since the stains 21 are dispersed and positioned without overlapping each other as one, the stains 21 may be less visually recognized compared with the embodiment of FIG. 3.

For example, the crystallization method according to the embodiment may increase the movement speed of the substrate 10 and performs the crystallization by repeatedly irradiating the laser beam, and the position of the substrate 10 may move in the y direction in each irradiation process of the substrate 10. Therefore, even if the stains 21 occur due to the defect 410 of the first mirror 400, the stains 21 may not overlap each other as a single stain (or overlapped stain) and be dispersed in each irradiation process, thereby reducing the visibility of the stains 21.

In FIGS. 5 to 7, after moving the substrate 10 in the y direction in each irradiation step, the irradiation is performed while moving it in the x direction, but in each irradiation process, by vibrating it in the y direction while moving the substrate 10 in the x axis, it is possible to further disperse the formation positions of the stains 21.

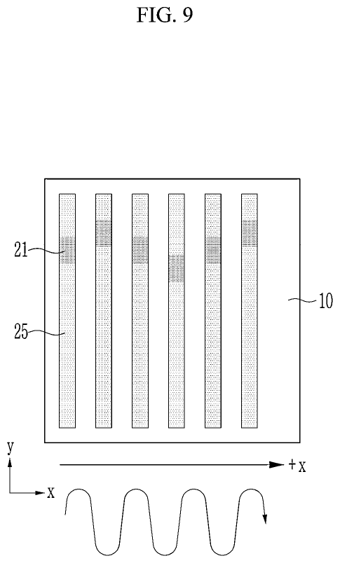

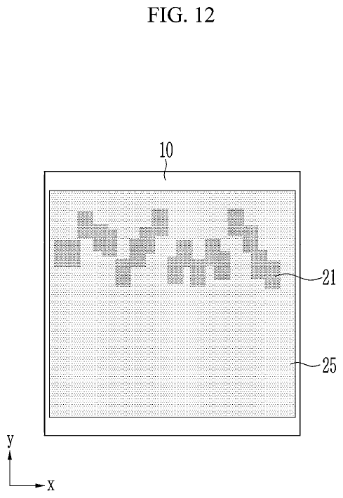

FIGS. 9 to 11 schematically illustrate an irradiation process of irradiating the laser beam on the substrate 10 and moving the substrate in both the x direction and the y directions, and FIG. 12 illustrates the crystallization silicon layer 25 crystallized through the laser beam irradiation of FIGS. 9 to 11.

Referring to FIG. 9, the substrate 10 may move in the +x direction, and the substrate 10 may move simultaneously in the y direction as shown in FIG. 9. In FIG. 9, the movement of the substrate 10 in the y direction may be in a form of vibrating up and down in the y direction, and the vibration of the substrate 10 in they direction may be combined with the movement of the substrate 10 in the x direction. Thus, the movement trajectory of the substrate 10 may be as indicated by an arrow (e.g., waveform arrow) in FIG. 9. The stains 21 may be dispersedly positioned in the crystallization silicon layer 25 crystallized by irradiating the laser beam. For example, compared with the embodiment of FIG. 5, the stains 21 of FIG. 5 may appear at constant positions, but in the embodiment of FIG. 9, the stains 21 may dispersedly appear.

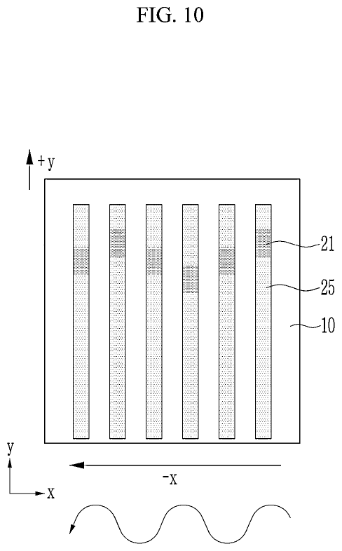

Referring to FIG. 10, the substrate 10 may move in the −x direction, and the substrate 10 may move simultaneously in they direction as shown in FIG. 10. In FIG. 10, the movement of the substrate 10 in they direction may be in a form of vibrating up and down in they direction, and the vibration of the substrate 10 in they direction may be combined with the movement of the substrate 10 in the x direction. Thus, the movement trajectory of the substrate 10 may be as indicated by an arrow (e.g., waveform arrow) in FIG. 10. The entire position of the substrate 10 may be in a state in which it further moves in the +y direction than a position (hereinafter, a reference position) of the substrate 10 in FIG. 9. For example, the entire position of the substrate 10 may be shifted in the +y direction than the reference position of the substrate 10 in FIG. 9. Referring to FIG. 10, the stains 21 may be dispersedly positioned in the crystallization silicon layer 25 crystallized by irradiating the laser beam. Since the entire substrate 10 further moves (or is shifted) in the +y direction from the reference position, the stains 21 may be positioned in the −y direction as a whole compared to the embodiment of FIG. 9.

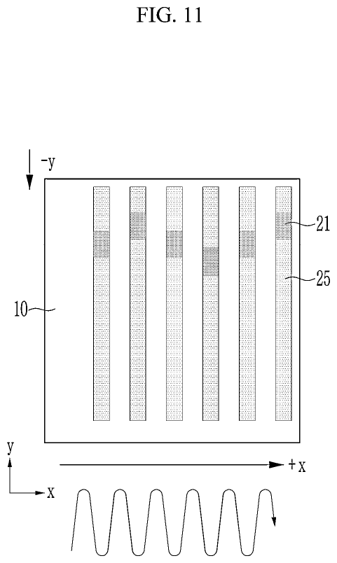

Referring to FIG. 11, the substrate 10 may move in the +x direction, and the substrate 10 may move simultaneously in the y direction as shown in FIG. 11. For example, the substrate 10 may move in the +x direction during the moving of the substrate 10 in the y direction as shown in FIG. 11. In FIG. 11, the movement of the substrate 10 in they direction may be in a form of vibrating up and down in the y direction, and the vibration in they direction may be combined with the movement in the x direction. Thus, the movement trajectory of the substrate 10 may be as indicated by an arrow (e.g., waveform arrow) in FIG. 11. The entire position of the substrate 10 may be in a state in which it further moves in the −y direction than a position (hereinafter, a reference position) of the substrate 10 in FIG. 9. Referring to FIG. 11, the stains 21 may be dispersedly positioned in the crystallization silicon layer 25 crystallized by irradiating the laser beam. Since the entire substrate 10 further moves (or is shifted) in the −y direction from the reference position, the stains 21 may be positioned in the +y direction as a whole compared to the embodiment of FIG. 9.

FIG. 12 schematically illustrates the crystallization silicon layer 25 crystallized through the laser irradiation process of FIGS. 9 to 11 as described above. Referring to FIG. 12, the stains 21 may be dispersed and positioned at various positions in the crystallization silicon layer 25 without being displayed as a line (or single line). In case that the laser beam is irradiated as in FIGS. 9 to 11 above, the laser beam may be irradiated on different positions of the substrate 10 in the +y and −y directions based on the reference position. In case that the substrate 10 moves in the x direction, the laser beam may be irradiated during the vibrating of the substrate 10 in they direction. Therefore, as shown in FIG. 12, the positions of the stains 21 may be dispersed in each irradiation process, and the stains 21 during each irradiation may not overlap each other as a single stain, but may be dispersed from each other to lower the visibility of the stains 21. For example, comparing the embodiments of FIGS. 3 and 12, in the embodiment of FIG. 3 that is continuously crystallized at once, the stains 21 may overlap and be viewed as a single line. However, in the embodiment of FIG. 12, since the stains 21 are dispersed and positioned without overlapping each other as one, the stains 21 may be less visually recognized compared with the embodiment of FIG. 3.

Comparing the embodiments of FIGS. 8 and 12, the stains 21 may be more dispersed, in the embodiment of FIG. 12 in which the movement in the x direction and the movement in the y direction are simultaneously performed in each laser irradiation step, compared with the embodiment of FIG. 8 in which only the movement in the x direction during the laser irradiation is performed.

In FIGS. 9 to 11, the width of vibration in they direction in each irradiation step may be different for each step. For example, in FIGS. 9 to 11, a path along which the substrate 10 moves is shown by the arrow (e.g., waveform arrow), and the size (e.g., amplitude) of the wavelength of each arrow (e.g., waveform arrow) may be different from each other. Thus, in case that the width of the vibration of the substrate 10 in the y direction is different in each irradiation step, the degree of overlap of the stains 21 may be reduced and the stains 21 may be dispersed, thereby reducing visibility thereof.

FIGS. 5 to 12 schematically illustrate configurations of crystallizing the amorphous silicon layer 20 by repeatedly irradiating the laser beam on the substrate 10 three times. However, this is only an example, and the number of repeatedly irradiating the substrate may vary according to embodiments. In case that the substrate 10 is irradiated n times, the movement speed of the substrate 10 in the x direction in each irradiation step may be n times faster than the reference speed.

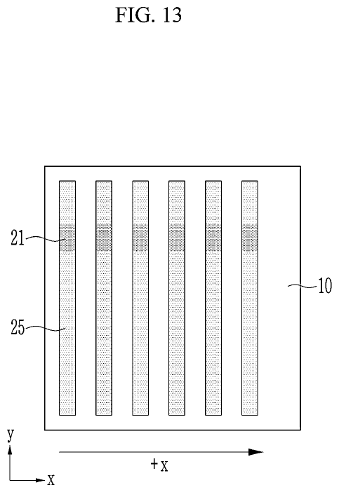

FIGS. 13 to 17 schematically illustrate configurations of crystallizing the amorphous silicon layer 20 by repeatedly irradiating the laser beam on the substrate 10 four times. Referring to FIG. 13, the amorphous silicon layer may be crystallized and the substrate 10 may move in the +x direction. For example, the amorphous silicon layer may be crystallized during the moving of the substrate 10 in the +x direction. FIG. 13 illustrates the crystallization silicon layer 25 in which amorphous silicon is crystallized and the stain 21 in which the crystallization is not sufficiently performed. The movement speed of the substrate 10 may be 4 times the reference speed.

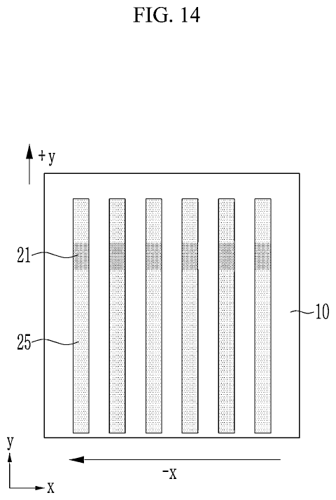

Referring to FIG. 14, the substrate 10 may move in the −x direction, and the amorphous silicon layer may be crystallized by irradiating the laser beam thereon. For example, the amorphous silicon layer may be crystallized by irradiating the laser beam on the substrate 10 during the moving of the substrate 10 in the −x direction. FIG. 14 schematically illustrates the crystallization silicon layer 25 crystallized by the irradiation with the laser beam and the stain 21 that is not sufficiently crystallized. The substrate 10 may move in the −x direction in a state in which it further moves in the +y direction than the position (hereinafter, the reference position) of the substrate 10 in FIG. 13. Accordingly, as shown in FIG. 14, the formation position of the stain 21 may be lower in the y direction than in FIG. 13. The laser beam may be irradiated in the state in which the substrate 10 moves in the +y direction, and the formation position of the stain 21 may be lower in they direction than the reference position of the substrate 10 shown in FIG. 13. The moving distance (or shifted distance) of the substrate 10 in the y direction based on the reference position may be in a range of about 1 cm to about 10 cm. However, this is only an example, and the moving distance in the y direction may vary according to embodiments.

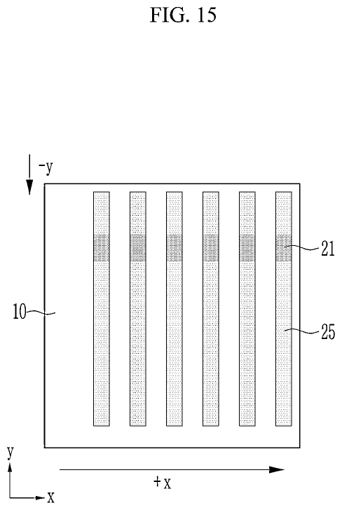

Referring to FIG. 15, the substrate 10 may move in the +x direction, and the amorphous silicon layer may be crystallized by irradiating the laser beam thereon. For example, the amorphous silicon layer may be crystallized by irradiating the laser beam on the substrate 10 during the moving of the substrate 10 in the +x direction. FIG. 15 illustrates the crystallization silicon layer 25 crystallized by the irradiation with the laser beam and the stain 21 that is not sufficiently crystallized. The substrate 10 may move in the +x direction in a state of moving in the −y direction from the reference position. Accordingly, as shown in FIG. 15, the formation position of the stain 21 may be higher in the y direction than in FIG. 13. This is because the laser beam is irradiated in the state in which the substrate 10 moves in the −y direction from the reference position. The moving distance (or shifted distance) of the substrate 10 in the y direction based on the reference position may be in a range of about 1 cm to about 10 cm. However, this is only an example, and the moving distance (or shifted distance) in the y direction may vary according to embodiments.

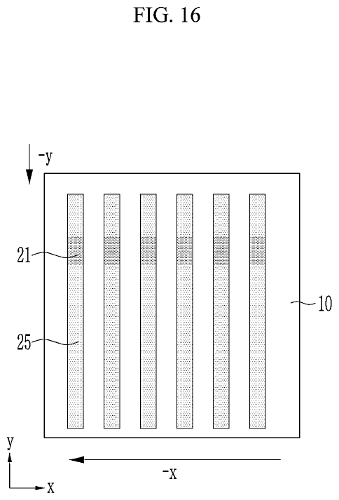

Referring to FIG. 16, the substrate 10 may move again in the −x direction, and the amorphous silicon layer may be crystallized by irradiating the laser beam thereon. For example, the amorphous silicon layer may be crystallized by irradiating the laser beam on the substrate during the moving of the substrate 10 in the −x direction. FIG. 16 illustrates the crystallization silicon layer 25 crystallized by the irradiation with the laser beam and the stain 21 that is not sufficiently crystallized. The substrate 10 may move in the −x direction in a state of moving in the +y direction from the reference position. Accordingly, as shown in FIG. 14, the formation position of the stain 21 may be lower in the y direction than in FIG. 13. The substrate 10 may move (or be shifted) in the +y direction from the reference position, and the laser beam may be irradiated on the substrate 10. The moving distance (or shifted distance) of the substrate 10 in they direction based on the reference position may be in a range of about 1 cm to about 10 cm. However, this is only an example, and the moving distance in the y direction may vary according to embodiments.

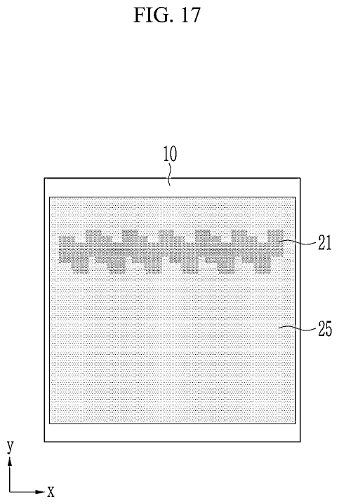

FIG. 17 schematically illustrates the crystallization silicon layer 25 crystallized by irradiating the laser beam as in FIGS. 13 to 16. Referring to FIG. 17, the stains 21 may be dispersed and positioned in the crystallization silicon layer 25 without being displayed as a line (or single line). In case that the laser beam is irradiated as in FIGS. 13 to 16 above, since the laser beam is irradiated on the substrate 10 with different positions from the reference position in the y direction, the position of the stain 21 may also be positioned at different positions for each irradiation. Accordingly, the stains 21 during each irradiation may not overlap as one (or single line), but may be dispersed from each other. Thus, visibility of the stains 21 may be lowered.

In FIGS. 13 to 16, the movement speed of the substrate 10 in each irradiation step may be 4 times the reference speed. For example, in case that the amorphous silicon layer 20 is crystallized by irradiating the laser beam on the substrate 10 n times, the movement speed of the substrate 10 in the x direction in each irradiation step may be n times faster than the reference speed.

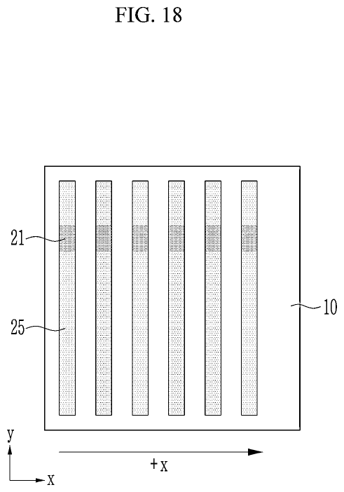

FIGS. 18 to 20 schematically illustrate configurations of crystallizing the amorphous silicon layer 20 by repeatedly irradiating the laser beam on the substrate 10 two times. Referring to FIG. 18, the substrate 10 may move in the +x direction, and the amorphous silicon layer may be crystallized. For example, the amorphous silicon layer may be crystallized during the moving of the substrate 10 in the +x direction. FIG. 18 illustrates the crystallization silicon layer 25 crystallized by the irradiation with the laser beam and the stain 21 that is not sufficiently crystallized. The movement speed of the substrate 10 may be 2 times the reference speed.

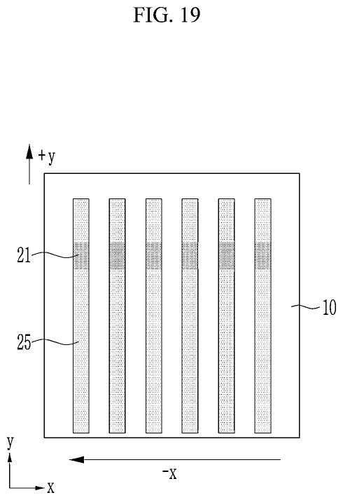

Referring to FIG. 19, the substrate 10 may move in the −x direction, and the amorphous silicon layer may be crystallized by irradiating the laser beam thereon. For example, the amorphous silicon layer may be crystallized by the irradiating of the laser beam thereon during the moving of the substrate 10 in the −x direction. FIG. 19 illustrates the crystallization silicon layer 25 crystallized by the irradiation with the laser beam and the stain 21 that is not sufficiently crystallized. The substrate 10 may move in the −x direction in a state in which it further moves in the +y direction than the position (hereinafter, the reference position) of the substrate 10 in FIG. 18. Accordingly, as shown in FIG. 19, the formation position of the stain 21 may be lower in the y direction than in FIG. 13. This is because the laser beam is irradiated in the state in which the substrate 10 moves in the +y direction. The moving distance (or shifted distance) of the substrate 10 in they direction based on the reference position may be in a range of about 1 cm to about 10 cm. However, this is only an example, and the moving distance (or shifted distance) in the y direction may vary according to embodiments.

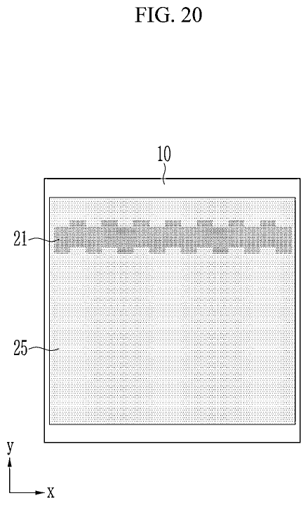

FIG. 20 schematically illustrates the crystallization silicon layer 25 crystallized by irradiating the laser beam as in FIGS. 18 and 19. Referring to FIG. 20, the stains 21 may be dispersed and positioned in the crystallization silicon layer 25 without being displayed as a line (or single line). In case that the laser beam is irradiated as in FIGS. 18 to 19 above, since the laser beam is irradiated on different positions of the substrate 10 in the y direction, the position of the stain 21 may also be positioned to be different for each irradiation. Accordingly, the stains 21 during each irradiation may not overlap as one (or single), but may be dispersed from each other. Thus, visibility of the stains 21 may be lowered. For example, comparing the embodiments of FIGS. 3 and 20, in the embodiment of FIG. 3 that is continuously crystallized at once, the stains 21 may overlap and be viewed as a single line, but in the embodiment of FIG. 20, since the stains 21 are dispersed and positioned without overlapping each other as one, the stains 21 may be less visually recognized compared with the embodiment of FIG. 3.

In the previous embodiment, the configuration of repeatedly irradiating the laser beam 2 to 4 times has been described as examples, but the disclosure is not limited thereto, and the number of irradiations may vary. As described above, in case that the number of irradiations is n times, the movement speed of the substrate 10 in the x direction may be n times faster than the reference speed. The position of the substrate 10 may move (or be shifted) in the y direction for each irradiation, and/or the substrate 10 may vibrate in the y direction during the irradiation. Thus, the overlapping of the stains 21 may be prevented, and the visibility of the stains 21 may be reduced in the crystallization silicon layer 25.

For example, in the crystallization method according to the embodiment, the movement speed of the substrate 10 may be increased, and the laser beam may be repeatedly irradiated. Thus, the crystallization may be performed, and the position of the substrate 10 may move (or be shifted) in the y and/or the substrate 10 may vibrate in the y direction, during the irradiation process of the substrate 10. Therefore, even if the stains 21 occur due to the defect 410 of the first mirror 400, the stains 21 may not overlap each other as a single stain (or overlapped stain) and be dispersed in the irradiation process, thereby reducing the visibility of the stains 21.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A crystallization method of amorphous silicon, comprising:
forming amorphous silicon on a substrate;
first-irradiating a laser beam on the amorphous silicon while moving the substrate in a first direction;
moving a position of the substrate in a second direction perpendicular to the first direction; and
second-irradiating a laser beam on the amorphous silicon while moving the substrate in an opposite direction to the first direction.

2. The crystallization method of amorphous silicon of claim 1, wherein
the laser beam is emitted from a laser beam source, and
the laser beam emitted from the laser beam source is reflected by a polygonal mirror that rotates around a rotation axis, and then is irradiated onto the substrate.

3. The crystallization method of amorphous silicon of claim 2, wherein:
the polygonal mirror includes:
a first reflective surface; and
a second reflective surface; and
a moving distance of a laser beam reflected by the first reflective surface on the substrate and a moving distance of a laser beam reflected by the second reflective surface on the substrate are equal to each other.

4. The crystallization method of amorphous silicon of claim 2, wherein
the laser beam reflected by the polygonal mirror is sequentially reflected by a first mirror and a second mirror and then is irradiated onto the substrate.

5. The crystallization method of amorphous silicon of claim 4, wherein
the first mirror has a convex reflective surface, and
the second mirror has a concave reflective surface.

6. The crystallization method of amorphous silicon of claim 1, wherein a moving distance of the substrate in the first direction in the first-irradiating of the laser beam and a moving distance of the substrate in the opposite direction to the first direction in the second-irradiating of the laser beam are equal to each other.

7. The crystallization method of amorphous silicon of claim 6, further comprising:
moving the position of the substrate in an opposite direction to the second direction; and
third-irradiating a laser beam on the amorphous silicon while moving the substrate in the first direction.

8. The crystallization method of amorphous silicon of claim 7, wherein a moving distance in the first direction in the third-irradiating of the laser beam and a moving distance in the first direction in the first-irradiating of the laser beam are equal to each other.

9. The crystallization method of amorphous silicon of claim 7, further comprising:
moving the position of the substrate in the second direction; and
fourth-irradiating a laser beam on the amorphous silicon while moving the substrate in the opposite direction to the first direction.

10. The crystallization method of amorphous silicon of claim 9, wherein a moving distance in the opposite direction to the first direction in the fourth-irradiating of the laser beam and a moving distance in the first direction in the third-irradiating of the laser beam are equal to each other.

11. The crystallization method of amorphous silicon of claim 1, wherein in the second-irradiating of the laser beam, a moving distance of the substrate in the second direction is in a range of about 1 cm to about 10 cm.

12. A crystallization method of amorphous silicon, comprising:
forming amorphous silicon on a substrate;
vibrating, while moving the substrate in a first direction, the substrate in a second direction perpendicular to the first direction, and first-irradiating a laser beam on the amorphous silicon during the moving;
moving a position of the substrate in the second direction; and
vibrating the substrate in the second direction while moving the substrate in an opposite direction to the first direction, and second-irradiating a laser beam on the amorphous silicon during the moving.

13. The crystallization method of amorphous silicon of claim 12, wherein a width of vibration in the second direction in the first-irradiating of the laser beam and a width of vibration in the second direction in the second-irradiating of the laser beam are different from each other.

14. The crystallization method of amorphous silicon of claim 12, wherein a moving distance of the substrate in the first direction in the first-irradiating of the laser beam and a moving distance of the substrate in the opposite direction to the first direction in the second-irradiating of the laser beam are equal to each other.

15. The crystallization method of amorphous silicon of claim 12, further comprising:
moving the position of the substrate in an opposite direction to the second direction; and
vibrating the substrate in the second direction while moving the substrate in the first direction, and third-irradiating a laser beam on the amorphous silicon during the moving.

16. The crystallization method of amorphous silicon of claim 15, further comprising:
moving the position of the substrate in the second direction; and
vibrating the substrate in the second direction while moving the substrate in the opposite direction to the first direction, and fourth-irradiating a laser beam on the amorphous silicon during the moving.

17. The crystallization method of amorphous silicon of claim 16, wherein a width of vibration in the second direction in the third-irradiating and a width of vibration in the second direction in the fourth-irradiating are different from each other.

18. The crystallization method of amorphous silicon of claim 12, wherein
in the second-irradiating of the laser beam, and
a moving distance of the substrate in the second direction is in a range of about 1 cm to about 10 cm.

19. The crystallization method of amorphous silicon of claim 12, wherein
the laser beam is emitted from a laser beam source, and
the laser beam emitted from the laser beam source is reflected by a polygonal mirror that rotates around a rotation axis, and then is irradiated onto the substrate.

20. The crystallization method of amorphous silicon of claim 19, wherein the laser beam reflected by the polygonal mirror is sequentially reflected by a first mirror and a second mirror and then is irradiated onto the substrate.
